(19) United States
(12) Patent Application Publication
(10) Pub. No.: US 2025/0138605 A1
(43) Pub. Date: May 1, 2025

(54) DISPLAY DEVICE INCLUDING PRINTED CIRCUIT MEMBER

(71) Applicant: LG Display Co., Ltd., Seoul (KR)

(72) Inventor: SeHwan Jeon, Paju-si (KR)

(73) Assignee: LG Display Co., Ltd., Seoul (KR)

(21) Appl. No.: 18/799,189

(22) Filed: Aug. 9, 2024

(30) Foreign Application Priority Data
Nov. 1, 2023 (KR) 10-2023-0149441

(51) Int. Cl. G06F 1/18; G06F 1/16

(52) U.S. Cl. CPC G06F 1/188; G06F 1/1656

(57) ABSTRACT

A display device according to embodiments of the disclosure may include a metal plate, a display panel disposed on the metal plate and including a backplate, a pixel circuit, and a light emitting element, and a printed circuit member including a driving circuit electrically connected to the display panel, the printed circuit member overlapping at least a portion of the metal plate. The metal plate may include a normal area and a rigid area disposed within a predetermined distance from the printed circuit member. The rigid area may include a plurality of roll pressed structures.

### CROSS-REFERENCE TO RELATED APPLICATION

This application claims priority from Korean Patent Application No. 10-2023-0149441, filed on Nov. 1, 2023, which is hereby incorporated by reference for all purposes as if fully set forth herein.

### BACKGROUND

### Field

The present disclosure relates to a display device including a printed circuit member.

### Description of Related Art

As technology in modern society develops, display devices are used in various ways to provide information to users. Display devices include not only electronic signs that simply deliver visual information unilaterally, but also various electronic devices that require higher technology to identify the user's input and provide information in response to the identified input.

A display device may include a display panel, a printed circuit member, and/or a printed circuit board. A driving circuit for driving the display panel or a controller may be disposed on the printed circuit member and/or the printed circuit board.

In some cases, the display panel and the printed circuit board may be connected through the printed circuit member. The printed circuit member may be bent so that the printed circuit board is disposed on the rear surface of the display panel. In this case, deformation, such as cracks, may occur at the portion where the printed circuit member and the display panel are coupled, and research is being conducted to prevent this.

### SUMMARY

Accordingly, the present disclosure is directed to a display device including a printed circuit member that substantially obviates one or more of the problems due to limitations and disadvantages of the related art.

An object of embodiments of the present disclosure is to provide a display device with minimized deformation at a portion where a printed circuit member and a display panel are connected to each other using a metal plate including a rigid area.

The objects of the present disclosure are not limited to the above-described objects, and other objects not mentioned can be clearly understood by those skilled in the art from the following description.

To achieve these objects and other advantages of the present disclosure, as embodied and broadly described herein, a display device according to embodiments of the disclosure may comprise a metal plate, a display panel disposed on the metal plate and including a backplate, a pixel circuit, and a light emitting element, and a printed circuit member including a driving circuit electrically connected to the display panel, the printed circuit member overlapping at least a portion of the metal plate. The metal plate may include a normal area and a rigid area disposed within a predetermined distance from the printed circuit member. The rigid area may include a plurality of roll pressed structures.

Specific details of other embodiments are included in the detailed description and drawings.

A display device according to embodiments of the disclosure may minimize deformation at a portion where a printed circuit member and a display panel are connected to each other using a metal plate including a rigid area.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a block diagram illustrating functions of a display device according to embodiments of the disclosure;

FIG. 2 is a view schematically illustrating a configuration of a display device according to embodiments of the disclosure.

FIG. 3 is a view illustrating a display device according to embodiments of the disclosure;

FIG. 4 is a view illustrating in greater detail a connection area of a display device according to embodiments of the disclosure;

FIG. 5 is a cross-sectional view taken along line A-A′ of FIG. 4;

FIG. 6 is a cross-sectional view illustrating a display device according to embodiments of the disclosure; and

FIGS. 7A, 7B, and 7C are views illustrating examples of a roll pressed structure according to embodiments of the disclosure.

### DETAILED DESCRIPTION

In the following description of examples or embodiments of the disclosure, reference will be made to the accompanying drawings in which specific examples or embodiments that can be implemented are shown by way of illustration. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

For use in embodiments of the disclosure, common terms widely used as possible have been chosen considering functions in the disclosure, but the terms may be varied depending on the intent of one of ordinary skill in the art or case laws or the advent of new technologies. In certain cases, some terms may be arbitrarily selected by the applicant, and in such case, their detailed definitions may be given in the relevant parts thereof. Accordingly, the terms used herein should be determined based on their meanings and the overall disclosure, rather than by the terms themselves.

As used herein, “at least one of a, b, and c” may encompass ‘a alone,’ ‘b alone,’ ‘c alone,’ ‘a and b,’ ‘a and c,’ ‘b and c,’ or ‘all of a, b, and c.’ Advantages and features of the disclosure, and methods for achieving the same may be understood through the embodiments to be described below taken in conjunction with the accompanying drawings.

The shapes, areas, proportions, angles, and numbers disclosed in the drawings to illustrate embodiments of the disclosure are merely examples and are not intended to limit the disclosure to those shown.

In the following description, where a detailed description of a relevant known function or configuration may unnecessarily obscure aspects of the present disclosure, a detailed description of such a known function or configuration may be omitted or be briefly discussed.

Where a term like “include,” “have,” or “composed of” is used, one or more other elements may be included unless the term is used with a more limiting term, such as “only.” An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “under,” “below,” “next to,” or the like, one or more other elements may be located between the two elements unless the term is used with a more limiting term, such as “immediate(ly)” or “direct(ly).” Where an element or layer is referred to as being “on” another element or layer, the element or layer may be positioned directly on the other element or layer, or one or more intervening elements or layers may be positioned therebetween.

Although terms “first,” “second,” and the like may be used herein to describe various elements, these elements should not be interpreted to be limited by these terms as they are not used to define a particular essence, order, sequence, precedence, or number of such elements. These terms are used only to refer one element separately from another. For example, a first element could be termed a second element, and a second element could similarly be termed a first element, without departing from the scope of the present disclosure.

The area, length, and thickness of each configuration shown in the drawings are shown for illustrative purposes only, and the disclosure is not necessarily limited to the area, length, and thickness of the configurations shown.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

The terms described below are defined considering functions in the disclosure. The terms may be varied depending on users' intentions, or customs. Therefore, the terms should be defined based on the overall disclosure.

The transistor constituting the pixel circuit of the disclosure may include at least one of an oxide thin film transistor (TFT), an amorphous silicon TFT (a-Si TFT), and a low temperature polysilicon (LTPS) TFT.

The description of the following embodiments focuses primarily on an organic light emitting display device. However, embodiments of the disclosure are not limited to organic light emitting display devices but may be applied to other types of display devices, including inorganic light emitting display devices including inorganic light emitting materials. For example, embodiments of the disclosure may also be applied to quantum dot display devices.

The terms like “first,” “second,” and “third” may be used to separately refer to components in one or more embodiments, but the disclosure is not limited by the terms. Therefore, it should be noted that the same term may denote different components according to embodiments.

Hereinafter, various embodiments of the present disclosure are described in detail with reference to the accompanying drawings.

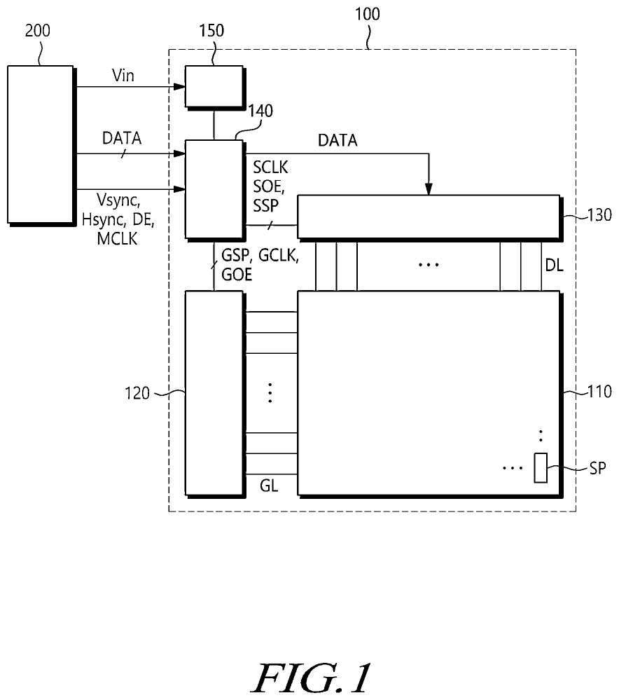

FIG. 1 is a block diagram illustrating functions of a display device according to embodiments of the disclosure;

As shown in FIG. 1, a display device 100 according to embodiments of the disclosure may include a display panel 110 where a plurality of gate lines GL and data lines DL are connected, and a plurality of subpixels SP are arranged in a matrix form, a gate driving circuit 120 driving the plurality of gate lines GL, a data driving circuit 130 supplying a data voltage through the plurality of data lines DL, a timing controller 140 controlling the gate driving circuit 120 and the data driving circuit 130, and a power management circuit 150.

The display panel 110 displays an image based on a scan signal transferred from the gate driving circuit 120 through the plurality of gate lines GL and the data voltage transferred from the data driving circuit 130 through the plurality of data lines DL.

In the case of an organic light emitting display, the display panel 110 may be implemented in a top emission scheme, a bottom emission scheme, or a dual-emission scheme.

In the display panel 110, a plurality of pixels may be arranged in a matrix form, and each pixel may include subpixels SP having different colors, e.g., a white subpixel, a red subpixel, a green subpixel, and a blue subpixel, and each subpixel SP may be defined by the plurality of data lines DL and the plurality of gate lines GL.

One subpixel SP may include, e.g., a thin film transistor (TFT) formed at the intersection between one data line DL and one gate line GL, a light emitting element, such as an organic light emitting diode, charged with the data voltage, and a storage capacitor electrically connected to the light emitting element to maintain the voltage.

For example, when the display device 100 having a resolution of 2,160×3,840 includes four subpixels SP of white (W), red (R), green (G), and blue (B), 3,840 data lines DL may be connected to 2,160 gate lines GL and four subpixels WRGB, and thus, there may be provided 3,840×4=15,360 data lines DL. Each subpixel SP is disposed at the intersection between the gate line GL and the data line DL.

The gate driving circuit 120 may be controlled by the controller 140 to sequentially output scan signals to the plurality of gate lines GL disposed in the display panel 110, controlling the driving timing of the plurality of subpixels SP.

The gate driving circuit 120 may include one or more gate driving integrated circuits (GDICs). Depending on driving schemes, the gate driving circuit 120 may be positioned on only one side, or each of two opposite sides, of the display panel 110. The gate driving circuit 120 may be implemented in a gate-in-panel (GIP) form which is embedded in the bezel area of the display panel 110.

The data driving circuit 130 receives image data DATA from the controller 140 and convert the received image data DATA into an analog data voltage. Then, as the data voltage is output to each data line DL according to the timing when the scan signal is applied through the gate line GL, each subpixel SP connected to the data line DL displays a light emitting signal having the brightness corresponding to the data voltage.

In an embodiment, the data driving circuit 130 may include one or more source driving integrated circuits SDIC, and the source driving integrated circuit SDIC may be connected to the bonding pad of the display panel 110 in a tape automated bonding (TAB) type or a chip-on-glass (COG) type or may be disposed directly on the display panel 110. In some cases, each source driving integrated circuit SDIC may be integrated and disposed on the display panel 110.

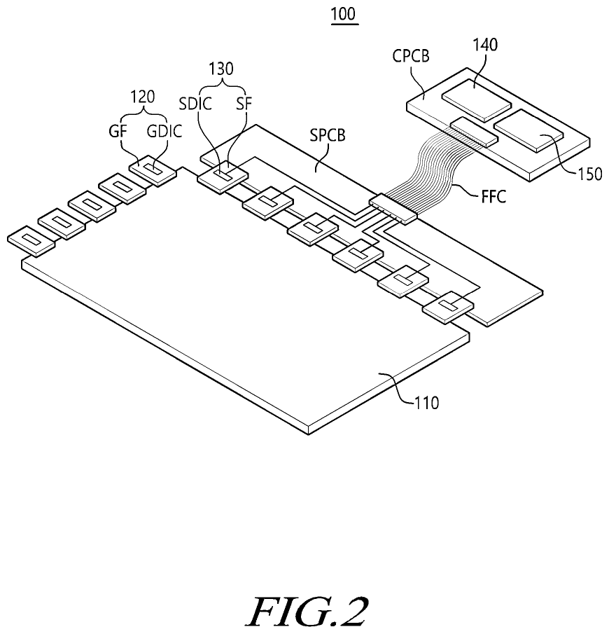

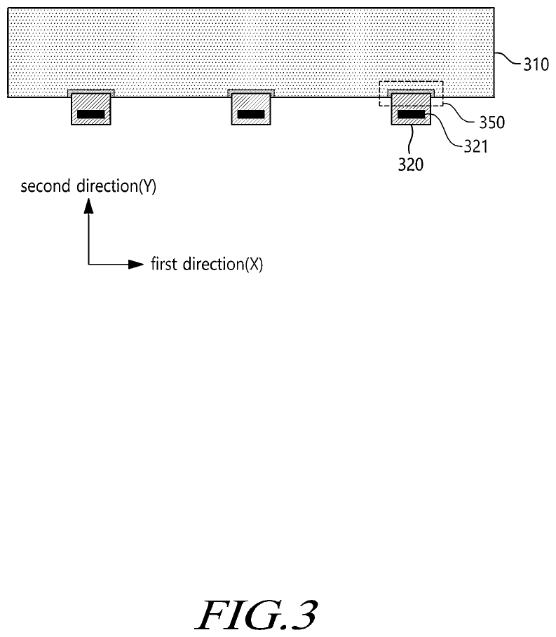

A source driving integrated circuit SDIC according to an embodiment of the disclosure may be implemented in a chip on film (COF) manner. The source driving integrated circuit SDIC may be mounted on a printed circuit member and electrically connected to the display panel 110 (or the data line DL of the display panel 110) through the printed circuit member. A more specific example related thereto may reference FIG. 2 and/or FIG. 3.

The controller 140 supplies various control signals to the gate driving circuit 120 and the data driving circuit 130 and controls the operation of the gate driving circuit 120 and the data driving circuit 130. For example, the controller 140 may control the gate driving circuit 120 to output a scan signal according to the timing implemented in each frame and, on the other hand, transfers the image data DATA received from the outside to the data driving circuit 130.

In this case, the controller 140 receives, from an external host system 200, several timing signals including, e.g., a vertical synchronization signal Vsync, a horizontal synchronization signal Hsync, a data enable signal DE, and a main clock MCLK, together with the image data DATA.

The host system 200 may be any one of, e.g., a television (TV) system, a set-top box, a navigation system, a personal computer (PC), a home theater system, a mobile device, and a wearable device.

The controller 140 may generate a control signal according to various timing signals received from the host system 200 and transfers the control signal to the gate driving circuit 120 and the data driving circuit 130.

In an embodiment, the controller 140 may output several gate control signals including, e.g., a gate start pulse GSP, a gate clock GCLK, and a gate output enable signal GOE, to control the gate driving circuit 120. The gate start pulse GSP controls the timing at which one or more gate driving integrated circuits GDIC constituting the gate driving circuit 120 start operation. The gate clock GCLK is a clock signal commonly input to one or more gate driving integrated circuits GDIC and controls the shift timing of the scan signal. The gate output enable signal GOE designates timing information about one or more gate driving integrated circuits GDICs.

In an embodiment, the controller 140 may output various data control signals including, e.g., a source start pulse SSP, a source sampling clock SCLK, and a source output enable signal SOE, to control the data driving circuit 130. The source start pulse SSP controls the timing at which one or more source driving integrated circuits SDIC constituting the data driving circuit 130 start data sampling. The source sampling clock SCLK is a clock signal that controls the timing of sampling data in the source driving integrated circuit SDIC. The source output enable signal SOE controls the output timing of the data driving circuit 130.

The display device 100 may further include a power management circuit 150 that supplies various voltages or currents to, e.g., the display panel 110, the gate driving circuit 120, and the data driving circuit 130 or controls various voltages or currents to be supplied.

The power management circuit 150 adjusts the direct current (DC) input voltage Vin supplied from the host system 200, generating power required to drive the display panel 100, the gate driving circuit 120, and the data driving circuit 130. The power management circuit 150 may be called a power management integrated circuit (PMIC).

The subpixel SP is positioned at the intersection between the gate line GL and the data line DL, and each subpixel SP may include a light emitting element. For example, the display device 100 may include a light emitting element, such as an organic light emitting diode, in each subpixel SP. The display device 100 may display an image by controlling the current flowing through the light emitting element according to the data voltage.

The display device 100 may be a device installed in various places in the interior space of a vehicle. For example, the display device 100 may be disposed (installed) on at least a portion of the dashboard of a vehicle. The dashboard of the vehicle is a component disposed in front of a front seats (e.g., driver's seat or passenger seat) of the vehicle. For example, the dashboard of the vehicle may be a component for manipulating various functions inside the vehicle (e.g., air conditioner, audio system, navigation system) or providing various information to the user of the vehicle.

In an embodiment, the display device 100 may be installed in an interior space (e.g., the ceiling of the vehicle or the back of the headrest of the driver's seat and/or the passenger seat, etc.) positioned behind the first row where the driver's seat and the passenger seat next to it are positioned. However, embodiments of the disclosure are not limited thereto.

FIG. 2 is a view schematically illustrating a configuration of a display device according to embodiments of the disclosure.

As shown in FIG. 2, in the display device 100 according to embodiments of the disclosure, the source driving integrated circuit SDIC included in the data driving circuit 130 and the gate driving integrated circuit GDIC included in the gate driving circuit 120 may be implemented in a chip-on-film (COF) type. According to an embodiment, the source driving integrated circuit SDIC and/or the gate driving integrated circuit GDIC may be referred to as a driving circuit.

One or more source driving integrated circuits SDIC included in the data driving circuit 130 each may be mounted on the printed circuit member SF, and one side of the printed circuit member SF may be electrically connected with the display panel 110. Lines for electrically connecting the source driver integrated circuit SDIC and the display panel 110 may be disposed on the printed circuit member SF.

The printed circuit member SF may be implemented in a film type but is not limited thereto. According to an embodiment, the printed circuit member SF may be referred to as a source film, a circuit film, or a printed circuit film, but is not limited by these terms.

The display device 100 may include a plurality of source driving integrated circuits SDIC and a printed circuit board for circuit connection between other devices. The printed circuit board may include, e.g., at least one source printed circuit board SPCB and a control printed circuit board CPCB for mounting control components and/or various electric devices.

In an embodiment, the other side of the printed circuit member SF may be connected to at least one source printed circuit board SPCB. In other words, one side of the printed circuit member SF may be electrically connected with the display panel 110, and the other side thereof may be electrically connected with the source printed circuit board SPCB.

The controller 140 and the power management circuit (power management IC) 150 may be mounted on the control printed circuit board CPCB. The controller 140 may control the operation of the data driving circuit 130 and the gate driving circuit 120. The power management circuit 150 may supply driving voltage or current to the display panel 110, the data driving circuit 130, and the gate driving circuit 120 and control the supplied voltage or current.

At least one source printed circuit board SPCB and control printed circuit board CPCB may be circuit-connected through at least one connection member. The connection member may include, e.g., a flexible printed circuit FPC or a flexible flat cable FFC. In this case, the connection member connecting the at least one source printed circuit board SPCB and control printed circuit board CPCB may be varied depending on the size and type of the display device 100.

According to an embodiment, at least one source printed circuit board SPCB and control printed circuit board CPCB may be integrated into a single printed circuit board.

In the so-configured display device 100, the power management circuit 150 may transfer a driving voltage necessary for display driving or characteristic value sensing to the source printed circuit board SPCB through the flexible printed circuit FPC or flexible flat cable FFC. The driving voltage transferred to the source printed circuit board SPCB may be supplied to emit light or sense a specific subpixel SP in the display panel 110 through the source driving integrated circuit SDIC.

In an embodiment, one or more gate driving integrated circuits GDIC included in the gate driving circuit 120 each may be mounted on a gate film GF, and one side of the gate film GF may be electrically connected with the display panel 110. Lines for electrically connecting the gate driving integrated circuit GDIC and the display panel 110 may be disposed on the gate film GF.

The gate driving circuit 120 may be located only on one side of the display panel 110 or on each of two opposite sides according to driving methods. The gate driving circuit 120 may be implemented in a gate-in-panel (GIP) form which is embedded in the bezel area of the display panel 110.

FIG. 3 is a view illustrating a display device according to embodiments of the disclosure. FIG. 3 is a view illustrating a display panel 310 (e.g., the display panel 110 of FIGS. 1 and 2) and a printed circuit member 320 according to embodiments of the disclosure.

A display device may include a display panel 310 and a printed circuit member 320. The display panel 310 may be implemented in various shapes. For example, the display panel 310 may be implemented in an irregular shape that is longer at the bottom than at the top. As another example, the display panel 310 may have a curved shape.

The printed circuit member 320 may include the printed circuit member SF of FIG. 2. A driving circuit 321 may be disposed on the printed circuit member 320. The driving circuit 321 may include the source driving integrated circuit SDIC of FIG. 2. The driving circuit 321 may be electrically connected to the display panel 310.

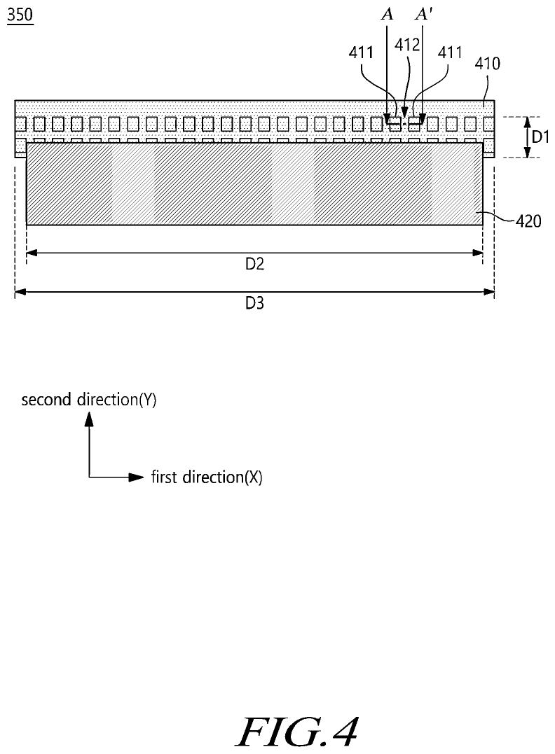

The printed circuit member 320 may be connected to the display panel 310. For example, the printed circuit member 320 may be connected to one side (or lower side) of the display panel 310. The area where the printed circuit member 320 and the display panel 310 are connected may be referred to as a connection area 350. A more specific example related to the connection area 350 may reference FIG. 4.

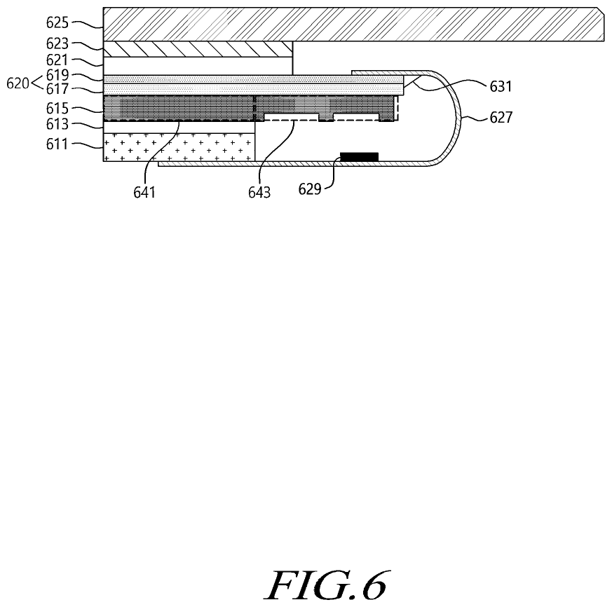

The printed circuit member 320 may be formed of a flexible material. At least a portion of the printed circuit member 320 may be bent behind the display panel 310. The printed circuit member 320 and the driving circuit 321 may be disposed on the rear surface of the display panel 310 based on at least a portion of the printed circuit member 320 being bent. A more specific example related thereto may reference FIG. 6.

As shown in FIG. 3, the display device may include a plurality of printed circuit members 320 and a driving circuit 321 disposed on each printed circuit member. FIG. 3 illustrates an example in which three printed circuit members 320 and three drive circuits 321 are disposed, but without limitations thereto, and more or less printed circuit members or driving circuits may be disposed, and the embodiments of the disclosure are not limited thereto.

FIG. 4 is a view illustrating in greater detail a connection area of a display device according to embodiments of the disclosure. FIG. 4 illustrates the connection area 350 of FIG. 3 in greater detail.

As shown in FIG. 4, the connection area 350 may include a rigid area 410. At least a portion of the rigid area 410 may be connected to the printed circuit member 420 (e.g., the printed circuit member 320 of FIG. 3).

The vertical length of the rigid area 410 may correspond to D1, and the horizontal length may correspond to D3. The length of the rigid area 410 in a first direction may correspond to D3, and the length of the rigid area 410 in a second direction may correspond to D1. The horizontal length of the printed circuit member 420 and/or the length of the printed circuit member 420 in the first direction may correspond to D2.

The rigid area 410 may include a plurality of roll pressed structures 411. The rigid area 410 may further include a rib structure 412 disposed between the plurality of roll pressed structures 411. The roll pressed structures are also called rolled structures or pressed structures.

D1 may be longer than twice the vertical length of the roll pressed structure included in the rigid area 410. D2 may be shorter than D3. D3 may be longer than D2. D3 may have a value of 104% or more of D2. For example, D3 may be 4% longer than D2. As another example, one side of D3 may be more than 2% longer than D2, and the other side of D3 may be more than 2% longer than D2.

In an embodiment, the plurality of roll pressed structures 411 may be disposed in two rows in the rigid area 410. The two rows may mean lines extending in the first direction. One of the two rows may be positioned closer to the printed circuit member 420 than the other. At least a portion of the roll pressed structure 411 included in the row disposed adjacent to the printed circuit member 420 may overlap the printed circuit member 420. At least a portion of the roll pressed structure 411 included in the remaining row may overlap the polarizing plate of the display panel. A more specific example related thereto may reference FIG. 6.

According to an embodiment, the plurality of roll pressed structures 411 may be disposed in three or more rows or in one row, but the embodiments of the disclosure are not limited thereto.

The plurality of roll pressed structures 411 may be provided on a metal plate disposed on the rear surface of the display panel (display panel 310 of FIG. 3). Since the display panel is disposed on the metal plate, the plurality of roll pressed structures 411 may not be visible. A more detailed description of the arrangement relationship between the display panel and the metal plate may reference FIG. 6.

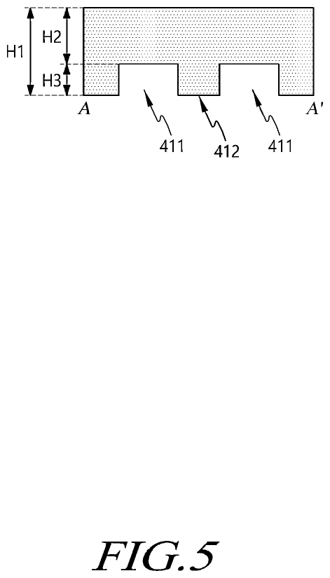

FIG. 5 is a cross-sectional view taken along line A-A′ of FIG. 4. FIG. 5 illustrates an example of a cross section for describing two roll pressed structures 411 and a rib structure 412 disposed around the roll pressed structures 411.

As shown in FIG. 5, the roll pressed structure 411 may correspond to a portion of the metal plate that is compressed. The rib structure 412 may be disposed between the roll pressed structures 411. The rib structure 412 may correspond to a portion of the metal plate that is not compressed.

In an embodiment, the height (or thickness) H1 of the rib structure 412 may be higher than the height H2 of the roll pressed structure 411. The height (or thickness) H2 of the roll pressed structure 411 may be smaller than the height H1 of the rib structure 412, but may be ⅔ or more of the height H1. The height H2 of the roll pressed structure 411 may be smaller than the height H1 of the rib structure 412, but may be 0.66 times the height H1 of the rib structure 412 or more. The roll pressed depth H3 may correspond to ⅓ (or 0.33 times) or less and 0 or more than the height H1 of the rib structure 412.

The metal plate may include a rigid area 410 where the roll pressed structure 411 and the rib structure 412 are positioned and a normal area other than the rigid area 410. The rib structure 412 may be an area positioned between the roll pressed structures 411 and having the same density as the normal area of the metal plate. In an embodiment, the density of the roll pressed structure 411 may be larger than the density of the rib structure 412. The roll pressed structure 411 may correspond to a compressed area. The roll pressed structure 411 may be formed as the metal plate is compressed in various manners, such as by a roller.

As the roll pressed structure 411 is disposed, the rigidity of the metal plate may be enhanced 20% or more. As the rib structure 412 is disposed, the rigidity of the metal plate may be enhanced 15% or more. As the height H2 of the roll pressed structure 411 is rendered to correspond to ⅔ or more of the height H1 of the rib structure, the rigidity of the metal plate may be enhanced while the flatness of the metal plate remains constant.

In an embodiment, a width of the rib structure 412 may be formed by the gap between the roll pressed structures 411. The roll pressed structures 411 may be disposed to have a predetermined gap, and the rib structure 412 may have a predetermined width.

In an embodiment, the roll pressed structure 411 may be formed flat. For example, as the roll pressed depth H3 is formed constant, the lower surface of the roll pressed structure 411 may be formed flat. However, without limitations thereto, according to an embodiment, the uniformity of the roll pressed depth H3 and the flatness of the roll pressed structure 411 may be changed.

The metal plate may be formed of aluminum. According to an embodiment, the metal plate may be painted with black pigment. In such a case, the roll pressed structure 411 and the rib structure 412 may also be painted with black pigment. The metal plate may be transparent and may be more resistant to temperature than the backplate. The backplate is described below with reference to FIG. 6.

FIG. 6 is a cross-sectional view illustrating a display device according to embodiments of the disclosure.

As shown in FIG. 6, a display panel 620 may be disposed on a metal plate 615. The display panel 620 may include a backplate 617 and a light emitting layer 619 that are sequentially stacked. In addition to the backplate 617 and the light emitting layer 619, the display panel 620 may include other various components that are omitted from the drawings for convenience of description.

The metal plate 615 may be formed of aluminum. The metal plate 615 may be opaque. According to an embodiment, the metal plate 615 may be painted with black pigment. When the metal plate 615 is painted with black pigment, the display device may implement a more complete black color than when the light emitting element is turned off.

As shown in FIG. 6, one end of the metal plate 615 toward the bending area may be formed to be shorter than one end of the display panel 620 toward the bending area. In this case, the metal plate 615 does not protrude beyond the display panel 620, thereby ensuring bending stability.

The display panel 620 may be disposed on the metal plate 615. The display panel 620 may include a light emitting element and various components for driving the light emitting element. For example, the display panel 620 may include a backplate 617 and a light emitting layer 619.

The backplate 617 may be formed of a plastic material. For example, the backplate 617 may be formed of polyethylene terephthalate (PET). The backplate 617 may be transparent, and be vulnerable to temperature and have weak rigidity as compared with the metal plate 615. The backplate 617 may be formed larger than the metal plate 615. Accordingly, as shown, an end of the backplate 617 may protrude beyond an end of the metal plate 615.

The light emitting layer 619 may be disposed on the backplate 617. The light emitting layer 619 may include a pixel circuit and a light emitting element. According to an embodiment, the light emitting layer 619 may include at least one of a substrate (e.g., a plastic substrate or a buffer layer), a light emitting element, a pixel circuit for allowing the light emitting element to emit light, a protection layer (or encapsulation layer) for protecting the light emitting element, and a touch layer (e.g., a touch electrode or a touch sensor) for implementing a touch function.

A printed circuit member 627 may be disposed at one end of the display panel 620. The printed circuit member 627 may overlap at least a portion of the metal plate 615. For example, a portion of the printed circuit member 627 connected to the display panel 620 may overlap at least a portion of the metal plate 615.

The printed circuit member 627 may be bent. Accordingly, at least a portion of the printed circuit member 627 may be disposed on the rear surface of the display panel 620. For example, the area of the printed circuit member 627 where the driving circuit 629 is disposed may be disposed on the rear surface of the display panel 620. At least a portion of the printed circuit member 627 disposed on the rear surface of the display panel 620 may be connected to the source printed circuit board 611.

One end of the printed circuit member 627 may be connected to the display panel 620, and the other end may be connected to the source printed circuit board (or SPCB) 611. According to an embodiment, the printed circuit member 627 may be connected to a control printed circuit board. A driving circuit 629 may be disposed on the printed circuit member 627. The driving circuit 629 may be electrically connected to the display panel 620.

According to an embodiment, a first adhesive member 631 may be disposed on a side surface of the display panel 620 and one surface of the printed circuit member 627 to adhere the display panel 620 and the printed circuit member 627. In some cases, the first adhesive member 631 may be implemented at other various positions, such as being disposed between the printed circuit member 627 and the display panel 620.

A first surface (or rear surface or lower surface) of the source printed circuit board 611 may be connected to the printed circuit member 627. A second adhesive member 613 may be disposed on a second surface (or front surface or upper surface) of the source printed circuit board 611. The source printed circuit board 611 may be electrically connected to the driving circuit 629.

The second adhesive member 613 may be disposed between the metal plate 615 and the source printed circuit board 611. The second adhesive member 613 may adhere the metal plate 615 and the source printed circuit board 611. The second adhesive member 613 may be implemented in a tape-like form but is not limited thereto.

A polarizing plate 621 may be disposed on the display panel 620. The polarizing plate 621 may control light emitted through the display panel 620. An adhesive layer 623 may be disposed on the polarizing plate 621. A cover layer 625 may be disposed on the adhesive layer 623. The cover layer 625 may be adhered to the polarizing plate 621 by the adhesive layer 623. The cover layer 625 may be formed of glass but is not limited thereto. As shown, an end of the cover layer 625 may be formed to be longer than an end of the display panel.

The metal plate 615 may include a normal area 641 and a rigid area 643. The rigid area 643 is an area including a roll pressed structure and a rib structure, and may be an area with enhanced rigidity compared to the normal area 641. The rigid area 643 may be disposed within a predetermined distance range from the printed circuit member 627. The normal area 641 may be the remaining area except for the rigid area 643.

The normal area 641 may overlap the source printed circuit board 611 and the adhesive member 613. The rigid area 643 may not overlap the source printed circuit board 611 and the adhesive member 613. A portion of the rigid area 643 may overlap the display panel 620, the polarizing plate 621, the adhesive layer 623, and the cover layer 625. Another portion of the rigid area 643 may overlap the display panel 620 and the printed circuit member 627 disposed on the display panel 620. Another portion of the rigid area 643 may not overlap the polarizing plate 621.

The rigid area 642 may include a plurality of roll pressed structures disposed in multiple rows. For example, the rigid area 642 may include a plurality of roll pressed structures disposed in two rows. Among the roll pressed structures in two rows, the roll pressed structure in the row disposed farther form the printed circuit member 627 may overlap the polarizing plate 621 and the cover layer 625. Among the roll pressed structures in two rows, the roll pressed structure in the row disposed closer to the printed circuit member 627 may not overlap the polarizing plate 621.

The rigid area 642 of the metal plate 615 may be disposed within a predetermined distance from the printed circuit member 627. For example, the rigid area 642 may be formed to have a predetermined width or more from an end of the display panel 620 connected to the printed circuit member 627. Here, the predetermined width may correspond to a length at which at least a portion of the rigid area 642 overlaps the polarizing plate 621 and the cover layer 625.

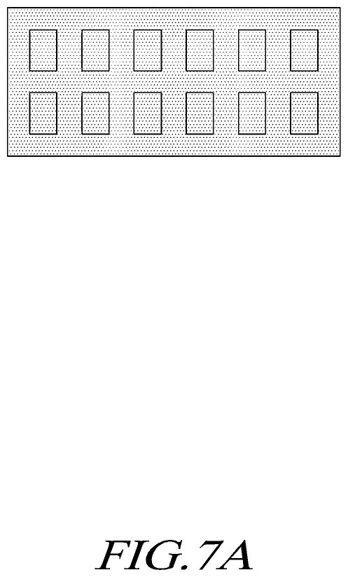

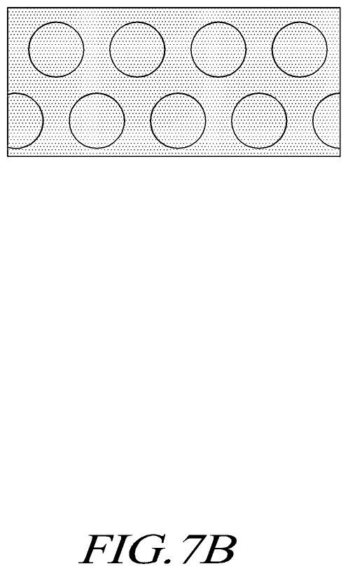

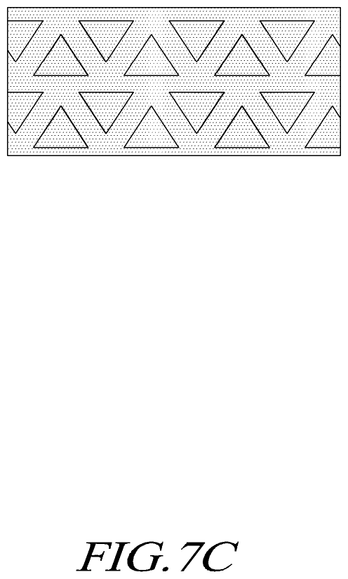

FIGS. 7A, 7B, and 7C are views illustrating examples of a roll pressed structure according to embodiments of the disclosure.

The plane of at least some of the plurality of roll pressed structures may have a triangular, square, or circular shape. As an example, as shown in FIG. 7A, the roll pressed structure may have a rectangular shape. For example, the length of the roll pressed structure in the first direction may be shorter than the length thereof in the second direction perpendicular to the first direction. In this case, the roll pressed structure may have a rectangular shape.

As shown in FIG. 7B, the roll pressed structure may have a circular shape. The distance between the centers of the closest roll pressed structures may be longer than the diameter of the roll pressed structure. At least some of the roll pressed structures may have a circular shape with a portion cut off. In this case, as shown, the circles at the ends may appear in cut shapes.

As shown in FIG. 7C, the roll pressed structure may have a triangular shape. In this case, the rolling structures may be disposed in four rows. However, this is merely an example, and more or less rows of roll pressed structures may be disposed.

A display device according to embodiments of the disclosure may comprise a metal plate, a display panel disposed on the metal plate, and including a backplate, a pixel circuit, and a light emitting element, and a printed circuit member where a driving circuit electrically connected to the display panel is disposed, the printed circuit member overlapping at least a portion of the metal plate. The metal plate may include a normal area and a rigid area disposed within a predetermined distance from the printed circuit member. The rigid area may include a plurality of roll pressed structures.

In an embodiment, the rigid area may further include a rib structure disposed between the plurality of roll pressed structures.

In an embodiment, a length of the rigid area in a first direction may be larger than a length of the printed circuit member in the first direction. The length of the rigid area in the first direction may be 4% or more larger than the length of the printed circuit member in the first direction.

In an embodiment, the display panel may further include a polarizing plate and a cover layer disposed on the polarizing plate. A portion of the rigid area may overlap the polarizing plate and the cover layer. Another portion of the rigid area may not overlap the polarizing plate. The plurality of roll pressed structures may be disposed in two rows in the rigid area. A roll pressed structure disposed in a row farther from the printed circuit member among the roll pressed structures in the two rows may overlap the polarizing plate and the cover layer.

In an embodiment, a height of the plurality of roll pressed structures may be smaller than a height of the rib structure. For example, the height of the plurality of roll pressed structures may be 0.66 times the height of the rib structure, or more. A density of the plurality of roll pressed structures may be larger than a density of the rib structure. The plane of at least some of the plurality of roll pressed structures may have a triangular, square, or circular shape.

In an embodiment, the backplate may include plastic, and the metal plate may include aluminum.

In an embodiment, the backplate may be disposed on the metal plate, the substrate may be disposed on the backplate, and the pixel circuit and the light emitting element may be disposed on the substrate.

In an embodiment, at least a portion of the printed circuit member may be bent. An end of the printed circuit member may be disposed on a front surface of the display panel, and another end of the printed circuit member may be disposed on a rear surface of the display panel.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed:

1. A display device, comprising:
a metal plate;
a display panel disposed on the metal plate and including a backplate, a pixel circuit, and a light emitting element; and
a printed circuit member including a driving circuit electrically connected to the display panel, the printed circuit member overlapping at least a portion of the metal plate,
wherein the metal plate includes a normal area and a rigid area disposed within a predetermined distance from the printed circuit member, and
wherein the rigid area includes a plurality of roll pressed structures.

2. The display device of claim 1, wherein a length of the rigid area in a first direction is larger than a length of the printed circuit member in the first direction.

3. The display device of claim 2, wherein the length of the rigid area in the first direction is 4% or more larger than the length of the printed circuit member in the first direction.

4. The display device of claim 1, wherein:
the display panel further includes a polarizing plate and a cover layer disposed on the polarizing plate; and
a portion of the rigid area overlaps the polarizing plate and the cover layer.

5. The display device of claim 4, wherein another portion of the rigid area does not overlap the polarizing plate.

6. The display device of claim 4, wherein:
the plurality of roll pressed structures are disposed in two rows in the rigid area; and
a roll pressed structure disposed in a row farther from the printed circuit member among the roll pressed structures in the two rows overlaps the polarizing plate and the cover layer.

7. The display device of claim 1, wherein the rigid area further includes a rib structure disposed between the plurality of roll pressed structures.

8. The display device of claim 7, wherein a height of the plurality of roll pressed structures is smaller than a height of the rib structure.

9. The display device of claim 8, wherein the height of the plurality of roll pressed structures is 0.66 times the height of the rib structure, or more.

10. The display device of claim 7, wherein a density of the plurality of roll pressed structures is larger than a density of the rib structure.

11. The display device of claim 1, wherein a plane of at least some of the plurality of roll pressed structures has a triangular, rectangular, or circular shape.

12. The display device of claim 1, wherein the backplate includes plastic, and the metal plate includes aluminum.

13. The display device of claim 1, wherein:
the display panel includes a substrate disposed on the backplate; and
the backplate is disposed on the metal plate, and the pixel circuit and the light emitting element are disposed on the substrate.

14. The display device of claim 1, wherein:
at least a portion of the printed circuit member is bent; and
an end of the printed circuit member is disposed on a front surface of the display panel, and another end of the printed circuit member is disposed on a rear surface of the display panel.

15. The display device of claim 1, wherein a vertical length of the rigid area is longer than twice a vertical length of the roll pressed structure.

16. The display device of claim 1, wherein the metal plate is opaque.

17. The display device of claim 1, wherein the metal plate is painted with black pigment.
